(19) United States
(12) Patent Application Publication
(10) Pub. No.: US 2026/0302725 A1
(43) Pub. Date: Oct. 1, 2026

(54) Laser System for Generating Single-Sideband Modulated Laser Radiation

(71) Applicant: Toptica Projects GmbH, Gräfelfing (DE)

(72) Inventors: Manfred Hager, Geretsried (DE); Martin Enderlein, München (DE); Sebastian Hepp, Denklingen (DE)

(73) Assignee: Toptica Projects GmbH, Gräfelfing (DE)

(21) Appl. No.: 19/477,392

(22) PCT Filed: Apr. 18, 2024
(86) PCT No.: PCT/EP2024/060588

§ 371 Date: Oct. 21, 2025

(30) Foreign Application Priority Data
Apr. 24, 2023 (DE) 102023110359.8

(51) Int. Cl. H01S 5/062; H01S 5/06

(52) U.S. Cl. CPC H01S 5/062; H01S 5/0604

(57) ABSTRACT

In an embodiment, a laser system includes a laser light source, a first modulation device and a second modulation device independent of the first modulation device. The laser light source to emit laser radiation. The first modulation device to provide frequency modulation of the laser radiation with a frequency modulation deviation at a modulation frequency. The second modulation device to provide amplitude modulation of the laser radiation with an amplitude modulation deviation at the same modulation frequency. The frequency modulation and the amplitude modulation are coupled to each other in a phase-locked manner, wherein the frequency modulation deviation, the amplitude modulation deviation and the relative phase of the frequency modulation and the amplitude modulation are set in such a way that the spectrum of the frequency-modulated and amplitude-modulated laser radiation has a carrier and a single-sideband spaced apart from the carrier by the amount of the modulation frequency.

### CROSS-REFERENCE TO RELATED APPLICATIONS

This application is a national phase entry of International Patent Application No. PCT/EP2024/060588, filed Apr. 18, 2024, which claims priority to German Patent Application No. DE102023110359.8, filed Apr. 24, 2023, the content of each being incorporated herein by reference in its entirety for all purposes.

### TECHNICAL FIELD

The present disclosure relates to a laser system with a laser light source and a modulation device for modulating the laser radiation so that the spectrum of the laser radiation comprises a carrier and a sideband.

Furthermore, the present disclosure relates to the use of such a laser system to generate an artificial guide star or to excite optical transitions in a quantum information system.

Finally, the present disclosure also relates to a method for generating single sideband modulated laser radiation.

### BACKGROUND

Known laser systems use sideband-modulated laser radiation, which is amplified and, for example, frequency-doubled. This can be used, for example, to resonantly excite sodium atoms in the mesosphere to fluorescence. In this way, a point-shaped artificial star (“guide star”) is created, which can be used as a reference for astronomical telescopes with adaptive optics. The requirements for suitable laser systems to generate such artificial guide stars are high. Ideally, a high power of 20 watts (W) or more is required, and that with a linewidth of a few gigahertz (GHz) to less than 5 megahertz (MHz) at the sodium resonance of 589 nanometers (nm) (sodium D-line). In order to achieve a sufficient intensity of the artificial guide star, the interaction between the laser and the few sodium atoms in the mesosphere must be as intense as possible. It should be noted that the electronic excitation scheme of the sodium atom is not a pure 2-level system. Of importance is, for example, in particular the hyperfine splitting of the excited fluorescence line. The hyperfine splitting causes the fluorescence electron to be optically pumped into a non-resonant state after a few excitation cycles, that is a state from which there is no resonant optical transition at the laser frequency (fluorescence frequency). After this, the electron is no longer available for fluorescence, which means an immediate loss of the associated atom for fluorescence backscattering. This can be countered by adding a second spectral component to the laser light, namely one at a so-called back-pump frequency in addition to that at the fluorescence frequency. The fluorescence frequency excites the fluorescence of the corresponding sodium resonance. The pump-back frequency is detuned from the fluorescence frequency by the amount corresponding to the hyperfine splitting of the relevant sodium line and causes the excitation electron to be “pumped back” from the non-resonant state and is thus once again available for the fluorescence process. In this way, the intensity of the fluorescent light can be significantly increased. The pump-back frequency is typically generated by frequency modulation (sideband modulation) of the laser. In this case, the laser spectrum consists of a carrier at the fluorescence frequency and at least one sideband at the return pump frequency.

In known laser systems, a semiconductor laser is used as the laser light source, whereby the back-pump sideband is generated by sinusoidal modulation of the injection current of the laser diode. Alternatively, the laser beam can be modulated with the aid of an electro-optical modulator arranged in the beam path behind the laser light source. Due to the sinusoidal modulation, sidebands are always symmetrically arranged around the carrier, that is with a lower and higher frequency than the carrier. However, only one of the sidebands is usually required for the application; in the best case, the second sideband at least does not interfere with the application.

In such laser systems, it can be disadvantageous that the part of the optical power in the unused sideband does not contribute to increasing the fluorescence and thus reduces the efficiency of the laser in generating fluorescent light. Accordingly, less power is available in the sideband that is actually used. Furthermore, it is possible that the unused second sideband generates additional scattered light (e.g., Rayleigh scattering) in many applications and thus reduces the signal-to-noise ratio.

In the context of the artificial guide star created by laser, a spectrum of the laser radiation used without a superfluous second sideband can have further significant advantages. For example, to increase the coupling of the laser radiation to the atomic transition, frequency modulation of the laser (“chirping”) is often used, in which the interaction of the laser with different velocity classes of the atomic ensemble is controlled. Any unnecessary frequency component in the laser spectrum can reduce the efficiency of this process. In addition, with the narrow-band laser Raman signals can be generated at both the frequency of the carrier and the frequencies of the sidebands (see also, for example, Vogt et al., “Detection and Implications of Laser-Induced Raman Scattering at Astronomical Observatories”, Phys. Rev. X, 2017), which interfere with the instruments used. With single-sideband modulated (OSSB—“optical single-sideband”) laser radiation, the number of Raman lines can be reduced by up to a third.

The frequency spacing between carrier and sideband is in the high MHz to GHz range for the applications of interest (for example, 1.7 GHZ for sodium hyperfine splitting). The direct generation of single-sideband modulated laser radiation, for example by serrodyne (sawtooth) modulation, is practically impossible to implement due to the high-frequency Fourier components involved.

Sideband modulated, especially single-sideband modulated laser radiation, is of interest for other applications besides the generation of artificial guide stars in astronomy. In many applications in atomic physics, quantum technology, including quantum information technology and spectroscopy, it is essential to maximize the time duration of the interaction of a laser beam with an atom or an ensemble of atoms. These applications include among others the laser cooling of atoms and, more generally, the generation of fluorescence signals, for example in spectroscopy. To maximize the interaction time, two-level systems that allow cyclic excitation are often used here. Examples of this are generally alkali atoms or alkaline earth ions, in which case again the hyperfine splitting in the ground state must be taken into account. In order to increase the efficiency of laser cooling or the generation of resonance fluorescence of these alkali atoms or alkaline earth ions, it is therefore also helpful and common here to provide a second laser frequency (typically by means of a complete second laser system) in addition to the carrier that drives the quasi-cyclic transition in the atom, whereby the frequency spacing of both components corresponds to the hyperfine splitting of the atomic ground state in order to bring the atoms back into the ground state of the quasi-cyclic transition by optical pumping so that they can contribute to fluorescence.

The second sideband, which is always present in conventionally modulated laser radiation, requires optical power in any case, which is, for example, disadvantageous if the laser is operated at its power limit.

### SUMMARY

The present disclosure relates to a laser system having a laser light source, a first modulation device, and a second modulation device independent of the first modulation device. The laser light source being set up to emit laser radiation during operation of the laser system. The first modulation device being set up for frequency modulation of the laser radiation. The frequency modulation being carried out with a frequency modulation deviation at a modulation frequency. The second modulation device being set up for amplitude modulation of the laser radiation. The amplitude modulation being carried out with an amplitude modulation deviation at the modulation frequency.

### BRIEF DESCRIPTION OF THE DRAWINGS

Aspects of the present disclosure are explained in more detail below with reference to the drawings showing exemplary embodiments. In the drawings:

FIG. 1 shows a schematic representation of a first embodiment of a laser system according to aspects of the present disclosure;

FIG. 2 shows spectra of the laser radiation after (a) frequency modulation and (b) amplitude modulation according to aspects of the present disclosure;

FIG. 3 shows a schematic representation of a second embodiment of a laser system according to aspects of the present disclosure;

FIG. 4 shows spectra of the laser radiation (a) after frequency modulation and amplitude modulation, (b) after frequency conversion, and (c) after frequency conversion with adjustment of the modulation parameters according to aspects of the present disclosure; and

FIG. 5 shows a schematic representation of a third embodiment of a laser system according to aspects of the present disclosure.

### DETAILED DESCRIPTION

Aspects of the present disclosure provides a laser system which comprises the following:
a laser light source, set up to emit laser radiation during operation of the laser system,
a first modulation device, set up for frequency modulation of the laser radiation, wherein the frequency modulation is carried out with a frequency modulation deviation at a modulation frequency,
a second modulation device independent of the first modulation device, set up for amplitude modulation of the laser radiation, wherein the amplitude modulation is carried out with an amplitude modulation deviation at the modulation frequency,
wherein the frequency modulation and the amplitude modulation are coupled to each other in a phase-locked manner and wherein the frequency modulation deviation, the amplitude modulation deviation and the relative phase of the frequency modulation and the amplitude modulation are set in such a way that the spectrum of the frequency-modulated and amplitude-modulated laser radiation has a carrier and a single sideband which is spaced apart from the carrier by the amount of the modulation frequency.

The present disclosure involves knowledge that it is possible to generate a single sideband spectrum by concatenating frequency modulation and amplitude modulation of an optical carrier signal (that is the laser radiation generated by the laser light source) with suitable parameter selection with regard to modulation deviation and relative phase of frequency modulation and amplitude modulation, that is a spectrum which has one carrier and one sideband, wherein the sideband in the spectrum is spaced from the carrier, that is from the frequency of the carrier signal, by the amount of the modulation frequency.

This approach can also be implemented with real modulation techniques, which rarely generate pure frequency modulation or pure amplitude modulation, but usually have a mixture of both types of modulation. For the purposes of the present disclosure, frequency modulation is thus to be understood as a modulation that predominantly causes frequency modulation of the laser radiation. Accordingly, an amplitude modulation in the sense of the present disclosure is a modulation which predominantly causes an amplitude modulation of the laser radiation. In other words, the first and second modulation devices differ from each other with respect to their respective modulation deviations of frequency modulation and amplitude modulation. In the first modulation device, the modulation deviation of the frequency modulation is greater than in the second modulation device; correspondingly, the modulation deviation of the amplitude modulation is smaller in the first modulation device than in the second modulation device. It can be seen that a single sideband spectrum can always be generated by setting the modulation parameters appropriately if the modulations imposed by the individual modulators have different proportions of frequency modulation and amplitude modulation.

It should be noted that the designations first and second modulation device do not imply a specific order of arrangement in the beam path of the laser radiation. An amplitude modulation after preceding frequency modulation of the laser radiation is just as possible as the reverse order.

The approach of the present disclosure has a number of features that include:
By saving optical power for the additional, unnecessary spectral sideband, it is possible to increase the power in the remaining two optical signal components (carrier and single sideband) while maintaining the overall power of an optical amplifier system used. This is, for example, relevant if the laser system as a whole (without the solution according to the present disclosure) is already operating at the power limit, but additional output power is required.
Laser systems in which the frequency of the carrier or the sideband is to be changed quickly and/or with a large frequency deviation (“laser frequency chirping”) can be realized efficiently with the aid of the present disclosure. Conventional implementations, for example with suppression of the unwanted sideband by a spectral filter (which can only be tracked comparatively slowly with regard to its passband spectrum), do not make this possible or only to a limited extent.
Aspects of the present disclosure enable the realization of single sideband laser systems at high modulation frequencies, for which a serrodyne modulation (sawtooth waveform) is not practicable or at least extremely difficult.
Aspects of the present disclosure enable the generation of single-sideband modulated laser radiation at wavelengths or frequencies for which no (mostly fiber-coupled) complex I/Q modulators (for example dual-drive or dual-parallel Mach-Zehnder modulators) are available. In contrast, the conventional generation of OSSB spectra with such modulators is based on the interaction of several electro-optical modulators and phase shifters in an interferometric arrangement. Several control loops are required to maintain the necessary interference conditions. Implementations of the present disclosure are significantly less complex and can in principle be implemented without restriction with regard to the wavelength.
Aspects of the present disclosure enable the realization of extremely robust single-sideband laser systems in a compact design (for example, in comparison to a narrowband spectral filter whose filter frequency must be precisely controlled and stabilized).
Aspects of the present disclosure enable the realization of single-sideband laser systems in combination with (non-linear) optical amplifiers or frequency conversion systems that influence the spectrum of the laser radiation. Hereby, the frequency modulation and amplitude modulation can be used to “precondition” the laser radiation, so to speak, so that the laser radiation only has the desired single-sideband modulated spectrum at the output in accordance with aspects of the present disclosure. The influences of amplification or frequency conversion on the spectrum are thereby compensated for in advance (more details on this will follow below).
Aspects of the present disclosure enable the realization of single-sideband laser systems with standard components. For example, OSSB modulation can be realized in conventional master oscillator/power amplifier (MOPA) systems without any additional optical components.

In an embodiment, the laser light source is a diode laser with at least one laser diode, and the first modulation device is set up to modulate the injection current of the laser diode. The modulation of the injection current is a suitable method of generating spectral sidebands. This type of “electronic” modulation is generally easier to implement. The laser system can thus be provided at a significantly lower cost than laser systems that work with alternative modulators, such as electro-optical modulators.

In an embodiment, at least one of the first and second modulation devices may comprise an electro-optic modulator, an acousto-optic modulator, an electro-absorption modulator and/or an interferometric modulator. Such modulators are common and commercially available components which can be used for frequency modulation or amplitude modulation in the laser system according to the present disclosure in a manner known per se.

In an embodiment, the laser system comprises at least one optical amplifier, set up to amplify the laser radiation. The optical amplifier is used to amplify the generated laser radiation up to the desired power in one or more stages. The optical amplifier can also be designed as a second modulation device, for example. The amplification of the optical amplifier can be modulated in a simple way in order to realize an amplitude modulation of the laser radiation. In an embodiment, the optical amplifier is implemented as a Raman fiber amplifier. One example Raman fiber amplifier is disclosed in EP 2 081 264 A1. Another example Raman fiber amplifier is disclosed in the publication by Luke R. Taylor et al. (“50 W CW visible laser source at 589 nm obtained via frequency doubling of three coherently combined narrow-band Raman fiber amplifiers”, Optics Express, Vol. 18, No. 8, 8540). However, other types of amplifiers are also possible.

In an embodiment, the laser system comprises a non-linear frequency converter, set up for frequency conversion, for example, for frequency doubling of the frequency-modulated and amplitude-modulated laser radiation. The frequency converter transforms the frequency of the laser radiation into the desired frequency range, for example by frequency doubling and/or sum frequency generation.

In an embodiment of the laser system, the frequency modulation deviation, the amplitude modulation deviation and the relative phase of the frequency modulation and the amplitude modulation are set in such a way that the spectrum of the frequency-modulated and amplitude-modulated laser radiation only has a carrier and a single sideband at the output of the optical amplifier or the non-linear frequency converter. In accordance with aspects of the present disclosure, as already mentioned above, by adjusting the frequency modulation deviation and amplitude modulation deviation and relative phase of frequency modulation and amplitude modulation, a type of preconditioning can be applied to the spectrum of the modulated laser radiation, which specifically ensures that only the laser radiation that can be used at the end, that is after amplification and possibly frequency conversion, has the desired single sideband spectrum. After frequency modulation and amplitude modulation, the spectrum of the laser radiation will then generally not yet be a single-sideband spectrum. This generally only results after amplification and, if necessary, frequency conversion. This possibility of preconditioning contrasts with and in some instances may be characterized as superior to conventional techniques that can only generate a single sideband spectrum before amplification and frequency conversion. With such techniques, the optical amplification and subsequent frequency conversion will in many cases namely result in the spectrum having unwanted sidebands again at the end. This can be avoided by implementing embodiments of the present disclosure invention.

With regard to the applications mentioned at the beginning, the frequency of the carrier in the spectrum of the laser radiation in one possible embodiment of the laser system corresponds to a fluorescence frequency and the frequency of the remaining sideband corresponds to a pump-back frequency, whereby the fluorescence frequency is resonant to the transition frequency of an (approximately cyclic) optical transition, for example in an atom, that is a line in the electronic excitation spectrum of the atom, in an atomic ensemble or in an atom-like solid-state system (for example quantum dot) as a component of a quantum information system, and the frequency spacing of the back-pump frequency from the fluorescence frequency corresponds with the hyperfine splitting of the optical transition. For the generation of an artificial guide star by fluorescence excitation of the sodium atoms in the mesosphere, the fluorescence frequency of the laser radiation should correspond to a wavelength of 589 nanometers (nm), while the frequency spacing of the pump-back frequency from the carrier frequency, that is 1.7 gigahertz (GHz). This frequency spacing corresponds to the hyperfine splitting of the relevant sodium line.

The present disclosure also proposes a method for generating single-sideband modulated laser radiation, having the steps of
generation of laser radiation,
frequency modulation of the laser radiation with a frequency modulation deviation at a modulation frequency,
amplitude modulation of the laser radiation with an amplitude modulation deviation at the modulation frequency,
wherein the frequency modulation and the amplitude modulation are coupled to each other in a phase-locked manner and wherein the frequency modulation deviation, the amplitude modulation deviation and the relative phase of the frequency modulation and the amplitude modulation are set in such a way that the spectrum of the frequency-modulated and amplitude-modulated laser radiation has a carrier and a single sideband which is spaced apart from the carrier by the amount of the modulation frequency.

In addition, optical amplification and/or frequency conversion of the frequency-modulated and amplitude-modulated laser radiation can be carried out. Hereby, the frequency modulation deviation, the amplitude modulation deviation and the relative phase of the frequency modulation and the amplitude modulation are adjusted in such a way that the spectrum of the frequency-modulated and amplitude-modulated laser radiation has a carrier and a single sideband which is spaced apart from the carrier by the amount of the modulation frequency only after the optical amplification and/or the non-linear frequency conversion.

In an embodiment, the frequency of the laser radiation is periodically varied between an initial value and a final value in addition to the frequency modulation (“chirping” or also called “frequency chirping”). In the Laser Guide Star application, this makes it possible to control the interaction of the laser radiation with different velocity classes of the ensemble of sodium atoms in the mesosphere. The frequency deviation of the chirping will be significantly larger than that of the frequency modulation, while the speed, that is the frequency of the chirping is significantly smaller than the modulation frequency.

The present disclosure also relates to a laser system having at least one laser source which emits a laser beam, a splitting element which splits the laser beam into at least two spatially separated partial beams, at least one optical fiber of the type described above, through which the partial beams propagate, the core regions of the optical fiber each guiding one of the partial beams, and at least one combining element which coherently superimposes the partial beams after propagation through the optical fiber. With the polarization-maintaining optical fiber of the present disclosure, a high-power laser system based on the principle of coherent combination of partial beams can be, for example, realized without the disadvantages known from the prior art with regard to pump absorption.

In the following description of the figures, the same reference symbols and the same terms are used for identical and corresponding elements.

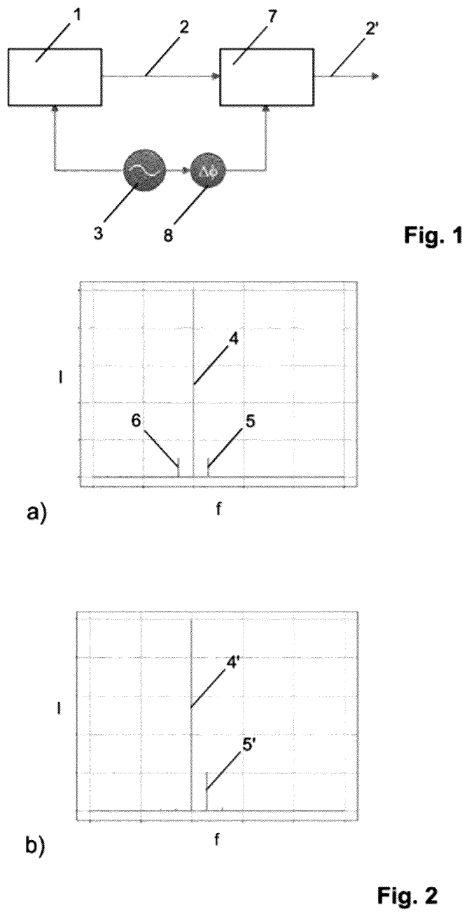

The laser system of FIG. 1 comprises a diode laser 1 as a laser light source that emits laser radiation 2. A first output of a high-frequency signal generator 3 is connected to an electronic signal input of the diode laser 1, so that the injection current of a laser diode (not shown) of the diode laser 1 is modulated with a modulation frequency according to the supplied signal. This causes a frequency modulation of the laser radiation 2. The high-frequency signal generator 3 thus forms a first modulation device with the laser diode in the sense of the present disclosure.

FIG. 2a shows the typical spectrum (in terms of intensity (I) as a function of the frequency (f)) of such frequency-modulated laser radiation 2 with a carrier 4 and two sidebands 5 and 6, which are arranged symmetrically to the carrier 4. The distance between carrier 4 and each of the sidebands 5, 6 is equal to the modulation frequency, that is the frequency of the output signal of the high-frequency signal generator 3.

In FIG. 1, an optical amplifier 7 is connected downstream of the diode laser 1 in the beam path. This emits amplified laser radiation 2′ at its output. The amplifier 7 has an electronic signal input which is coupled to a second output of the high-frequency signal generator 3 via a phase shifter 8. The signal fed to the amplifier 7 through the signal input causes a modulation of the optical amplification, that is an amplitude modulation of the laser radiation 2′. Thus, the high-frequency signal generator 3 with the amplifier 7 forms a second modulation device within the meaning of the present disclosure.

The signal at the second output of the high-frequency signal generator 3 has a fixed phase relationship to the signal present at the first output. The signals present at the two outputs are therefore coupled in a phase-locked manner. Accordingly, the frequency modulation and amplitude modulation of the laser radiation are coupled in a phase-locked manner. In contrast, the signal amplitudes at the two outputs of the high-frequency signal generator 3 (and thus the frequency modulation deviation and the amplitude modulation deviation) are freely adjustable. The relative phase between the modulation signals supplied to the diode laser 1 and the amplifier 7, that is the relative phase between frequency modulation and amplitude modulation, can also be set using the phase shifter 8.

FIG. 2b shows the spectrum of the laser radiation 2′ at the output of the amplifier 7. It can be seen that a single sideband modulation is achieved by suitable selection of the modulation parameters, that is the frequency modulation deviation, the amplitude modulation deviation and the relative phase. The spectrum shows the carrier 4′ and, compared to FIG. 2a, only a single sideband 5′. Minor spectral components that may occur in practice at other sideband frequencies, as can be faintly seen in FIG. 2b, can be ignored. The intensity of the single sideband 5′ is at least one order of magnitude stronger.

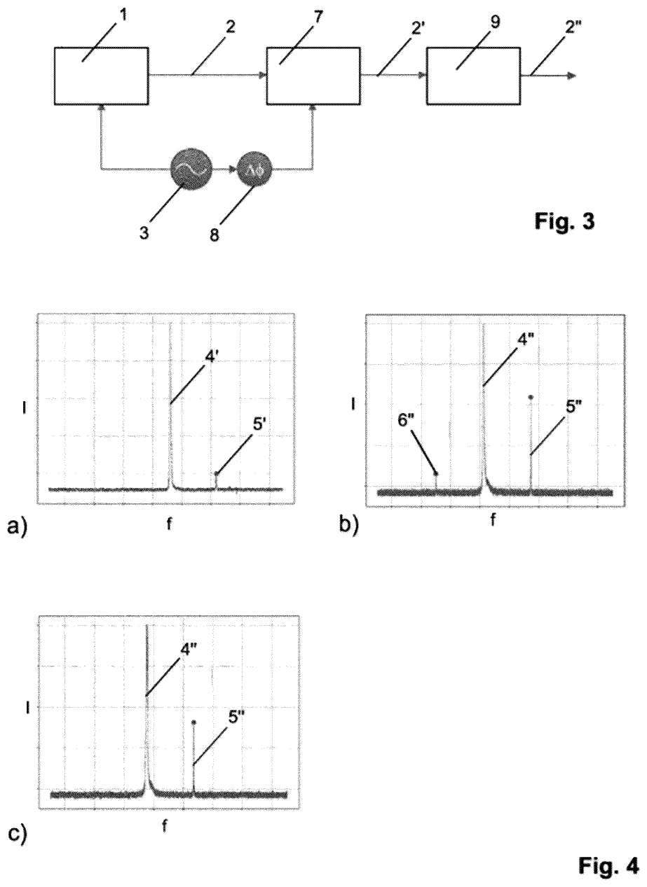

In the embodiment shown in FIG. 3, a non-linear frequency converter 9 is connected downstream of the optical amplifier 7, which emits a frequency-converted laser radiation 2″ at its output compared to the laser radiation 2′.

FIG. 4a shows the spectrum of the single-sideband modulated laser radiation 2′ at the output of the amplifier 7, analogous to FIG. 2b. FIG. 4b shows the corresponding spectrum of the laser radiation 2″ at the output of the frequency converter 9. It can be seen that the spectrum now again has a (frequency-converted) carrier 4″ and two sidebands 5″, 6″. Due to the non-linear frequency conversion, two sidebands 5″, 6″ have again been created from the spectrum in FIG. 4a. However, by suitably adjusting the modulation parameters, that is the frequency modulation deviation, the amplitude modulation deviation and the relative phase in the arrangement shown in FIG. 3, a single sideband modulation can also be achieved in this embodiment, as shown in FIG. 4c. With the modulation parameters corresponding to FIG. 4c, however, the laser radiation 2′ at the output of the amplifier 7 is no longer single-sideband modulated. However, these modulation parameters cause preconditioning of the laser radiation 2′ in such a way that the desired single-sideband modulation only with (frequency-converted) carrier 4″ and sideband 5″ is again produced at the output of the frequency converter 9, that is in the laser radiation 2″.

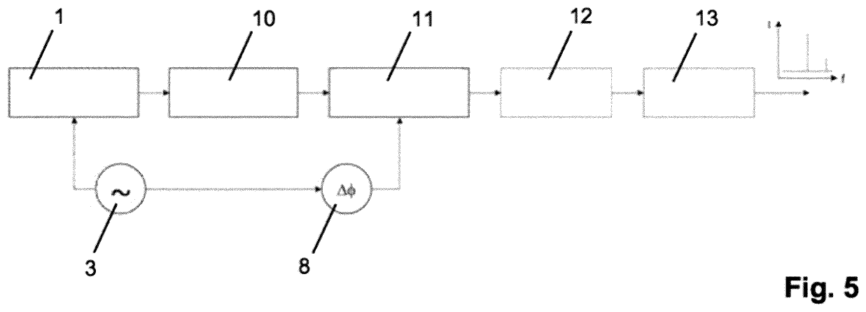

FIG. 5 shows an embodiment that is suitable, for example, for the Laser Guide Star application mentioned above. The laser system shown in FIG. 1 again comprises a laser light source 1, which is a diode laser. The laser light source 1 is connected to the high-frequency signal generator 3 so that the injection current of the laser diode (not shown) of the laser light source 1 is modulated at high frequency. The modulation frequency is 1.7 gigahertz (GHz). This modulation frequency gives the spectrum of the radiation emitted by the laser light source 1 a sideband, which is the basis for the generation of radiation at the pump-back frequency corresponding to the hyperfine splitting of the sodium D-line. The spectrum of the radiation emitted by the laser light source 1 has a component at a carrier frequency of 1178 nanometers (nm). The frequency spacing from the carrier frequency to the two sidebands is ±1.7 gigahertz (GHz), corresponding to the modulation frequency. The frequency-modulated laser radiation is fed via an optical fiber to a non-modulated semiconductor amplifier 10 as the first amplification stage. Downstream to this, again connected via an optical fiber, is an amplitude modulator 11 based on an electro-optical modulator, which is controlled by the second output of the high-frequency signal generator 3 via the phase shifter 8. The modulation characteristics (with regard to the proportions of frequency modulation and amplitude modulation) of the amplitude modulator 11 differ significantly from those of the diode laser 1, which may be useful for some implementations of the present disclosure. From the amplitude modulator 11, the laser radiation is again transmitted via an optical fiber to a Raman fiber amplifier 12. The amplifier fiber (not shown) of the fiber amplifier 12 is optically pumped by means of a pump laser (not shown). The Raman fiber amplifier 12 amplifies the laser radiation at the carrier frequency and at the sideband frequencies. The amplification bandwidth of the Raman fiber amplifier 12 is correspondingly large. At the output of the Raman fiber amplifier 12, the total power of the laser radiation is approximately 30 to 40 watts (W). In some implementations of the present disclosure, more than 100 watts (W) is practically feasible. The amplified laser radiation at the output of the Raman fiber amplifier 12 is then fed to a resonant frequency converter 13. This is a non-linear crystal located inside an optical resonator (both not shown). The (double resonant) frequency converter 13 converts the amplified radiation by frequency doubling and sum frequency generation. The spectrum of the single-sideband modulated laser radiation at the output of the frequency converter 13 then comprises, with appropriate adjustment of the modulation parameters, intensities at a fluorescence frequency (carrier) and a back-pump frequency (sideband), wherein the fluorescence frequency corresponds with the sodium D-line and the frequency spacing of the back-pump frequency from the fluorescence frequency corresponds with the hyperfine splitting of the corresponding sodium D-line. The power of the radiation at the output of the frequency converter 13 can be well above 20 watts (W), which is used, for example, for the generation of an artificial guide star for astronomical telescopes with adaptive optics. The single-sideband modulated spectrum of the amplified laser radiation results after frequency doubling or sum frequency generation by means of the frequency converter 13. The carrier is generated at the fluorescence frequency of 589 nanometers (nm). This central spectral line is produced by frequency doubling of the original carrier frequency. Furthermore, the amplified spectrum shows a single sideband, which is separated from the fluorescence frequency by 1.7 gigahertz (GHz). This sideband is generated by sum frequency generation of the carrier and the sideband of the original spectrum (the laser radiation at the output of the Raman fiber amplifier 12. The sideband at 1.7 gigahertz (GHz) obtained by sum frequency generation is present at the pump-back frequency. For a high fluorescence yield, the intensity at the pump-back frequency should be at least 10 % of the intensity at the fluorescence frequency. To achieve this, sum frequency generation is used. This uses the fact that the resulting intensity at the sum frequency generation behaves like the products of the intensities of the fundamental light fields.

The present disclosure provides for a laser system and a method that generates single-sideband modulated laser radiation in a practicable way, with a frequency separation between carrier and sideband in the (high) megahertz (MHz) to gigahertz (GHz) range.

1. A laser system comprising:
a laser light source configured to emit laser radiation during operation of the laser system;
a first modulation device configured for frequency modulation of the laser radiation with a frequency modulation deviation at a modulation frequency;
a second modulation device independent of the first modulation device, the second modulation device configured for amplitude modulation of the laser radiation with an amplitude modulation deviation at the modulation frequency,
wherein the frequency modulation and the amplitude modulation are coupled to each other in a phase-locked manner, and
wherein the frequency modulation deviation, the amplitude modulation deviation and the relative phase of the frequency modulation and the amplitude modulation are set in such a way that the spectrum of the frequency-modulated and amplitude-modulated laser radiation has a carrier and a single-sideband which is spaced apart from the carrier by the amount of the modulation frequency.

2. The laser system according to claim 1, wherein the laser light source is a diode laser with at least one laser diode, and wherein the first modulation device is configured for modulation of the injection current of the laser diode.

3. The laser system according to claim 1, wherein at least one of the first and second modulation devices comprises an electro-optic modulator, an acousto-optic modulator, an electro-absorption modulator or an interferometric modulator.

4. The laser system according to claim 1, further comprising at least one optical amplifier configured for amplification of the laser radiation in one or more stages.

5. The laser system according to claim 1, further comprising a non-linear frequency converter configured for frequency conversion of the frequency-modulated and amplitude-modulated laser radiation.

6. The laser system according to claim 4, wherein the frequency modulation deviation, the amplitude modulation deviation and the relative phase of the frequency modulation and the amplitude modulation are set in such a way that the spectrum of the frequency-modulated and amplitude-modulated laser radiation at the output of the optical amplifier has a carrier and a single sideband.

7. The laser system according to claim 6, wherein the frequency of the carrier in the spectrum of the frequency-modulated and amplitude-modulated laser radiation at the output of the optical amplifier corresponds to a fluorescence frequency and the frequency of the single sideband corresponds to a pump-back frequency,
wherein the fluorescence frequency is resonant with a transition frequency of an optical transition, and
wherein the frequency spacing of the pump-back frequency from the fluorescence frequency is resonant with the hyperfine splitting of the optical transition.

8. The laser system according to claim 7, wherein the fluorescence frequency corresponds to the transition frequency of the sodium line at a wavelength of 589 nanometers (nm) and the frequency spacing of the pump-back frequency from the fluorescence frequency is 1.7 gigahertz (GHz).

9. The laser system according to claim 1, wherein the laser system is configured for generation of an artificial guide star (“laser guide star”) for astronomical telescopes with adaptive optics.

10. The laser system according to claim 1, wherein the laser system is configured for excitation of optical transitions in a quantum information system.

11. A method for generating single-sideband modulated laser radiation, comprising:
generation of laser radiation;
frequency modulation of the laser radiation with a frequency modulation deviation at a modulation frequency; and
amplitude modulation of the laser radiation with an amplitude modulation deviation at the modulation frequency,
wherein the frequency modulation and the amplitude modulation are coupled to each another in a phase-locked manner, and
wherein the frequency modulation deviation, the amplitude modulation deviation and the relative phase of the frequency modulation and the amplitude modulation are set in such a way that the spectrum of the frequency-modulated and amplitude-modulated laser radiation has a carrier and a single sideband which is spaced apart from the carrier by the amount of the modulation frequency.

12. The method according to claim 11, further comprising an optical amplification of the frequency-modulated and amplitude-modulated laser radiation.

13. The method according to claim 11, further comprising non-linear frequency conversion of the frequency-modulated and amplitude-modulated laser radiation.

14. The method according to claim 12, wherein the frequency modulation deviation, the amplitude modulation deviation and the relative phase of the frequency modulation and the amplitude modulation are set up in such a way that the spectrum of the frequency-modulated and amplitude-modulated laser radiation after the optical amplification has a carrier and a single sideband which is spaced apart from the carrier by the amount of the modulation frequency.

15. The method according to claim 11, wherein the frequency of the laser radiation is periodically varied between an initial value and a final value in addition to the frequency modulation.

16. The laser system according to claim 5, wherein the frequency modulation deviation, the amplitude modulation deviation and the relative phase of the frequency modulation and the amplitude modulation are set in such a way that the spectrum of the frequency-modulated and amplitude-modulated laser radiation at the output of the non-linear frequency converter has a carrier and a single sideband.

17. The laser system according to claim 16, wherein the frequency of the carrier in the spectrum of the frequency-modulated and amplitude-modulated laser radiation at the output of the non-linear frequency converter corresponds to a fluorescence frequency and the frequency of the single sideband corresponds to a pump-back frequency, wherein the fluorescence frequency is resonant with a transition frequency of an optical transition, and wherein the frequency spacing of the pump-back frequency from the fluorescence frequency is resonant with the hyperfine splitting of the optical transition.

18. The laser system according to claim 17, wherein the fluorescence frequency corresponds to the transition frequency of the sodium line at a wavelength of 589 nanometers (nm) and the frequency spacing of the pump-back frequency from the fluorescence frequency is 1.7 gigahertz (GHz).

19. The method according to claim 13, wherein the frequency modulation deviation, the amplitude modulation deviation and the relative phase of the frequency modulation and the amplitude modulation are set up in such a way that the spectrum of the frequency-modulated and amplitude-modulated laser radiation after the non-linear frequency conversion has a carrier and a single sideband which is spaced apart from the carrier by the amount of the modulation frequency.

20. The method according to claim 19, wherein the frequency of the carrier in the spectrum of the frequency-modulated and amplitude-modulated laser radiation after the non-linear frequency conversion corresponds to a fluorescence frequency and the frequency of the single sideband corresponds to a pump-back frequency, wherein the fluorescence frequency is resonant with a transition frequency of an optical transition, and wherein the frequency spacing of the pump-back frequency from the fluorescence frequency is resonant with the hyperfine splitting of the optical transition.
